(19) United States
(12) Patent Application Publication
(10) Pub. No.: US 2026/0259513 A1
(43) Pub. Date: Sep. 3, 2026

(54) ORIENTABLE SEMICONDUCTOR CONTAINER AND ORIENTATION SYSTEM FOR SEMICONDUCTOR CONTAINER

(71) Applicant: GUDENG PRECISION INDUSTRIAL CO., LTD., NEW TAIPEI (TW)

(72) Inventors: MING-CHIEN CHIU, NEW TAIPEI (TW); CHIA-HO CHUANG, NEW TAIPEI (TW); PIN-CHENG CHEN, NEW TAIPEI (TW); YEN-CHENG TU, NEW TAIPEI (TW); HSIN-MIN HSUEH, NEW TAIPEI (TW); YA-SHI WANG, New Taipei (TW)

(21) Appl. No.: 19/545,104

(22) Filed: Feb. 20, 2026

Related U.S. Application Data
(60) Provisional application No. 63/762,790, filed on Feb. 25, 2025.

(51) Int. Cl. G03F 7/00; G03F 1/66; H10P 72/10; H10P 72/50

(52) U.S. Cl. CPC G03F 7/70991; G03F 1/66; G03F 7/70741; H10P 72/1906; H10P 72/50

(57) ABSTRACT

An orientable semiconductor container provided by the present invention is adapted to a non-equilateral rectangular reticle pod, and includes a pod and an orientating assembly disposed at a bottom of the pod. The orientating assembly is configured to cooperate with a drive portion of a load port when the pod is placed on the load port, and rotate the pod from a first direction to a second direction according to a drive stroke provided by the drive portion. The present invention further provides an orientation system for a semiconductor container. With the cooperation between the orientating assembly and the drive portion, the orientating assembly rotates the non-equilateral rectangular reticle pod from a first direction to a second direction according to a drive stroke provided by the drive portion.

### CROSS-REFERENCE TO RELATED APPLICATION

This application claims priority to and benefits of U.S. Provisional Application No. 63/762,790, filed February 25, 2025, the content of which is incorporated by reference herein in its entirety.

### BACKGROUND OF THE INVENTION

### FIELD OF THE INVENTION

The present invention relates to a semiconductor container, and more particularly to an orientable semiconductor container and a semiconductor container orientation system for receiving the semiconductor container.

### DESCRIPTION OF THE PRIOR ART

As dimensions of reticles are enlarged from 6 inches by 6 inches to 6 inches by 12 inches, a large-sized non-equilateral rectangular reticle transport pod developed has a long side and a short side in order to load such non-equilateral rectangular reticle with enlarged dimensions. In response to the enlarged non-equilateral rectangular shapes of the reticle and dimensions of the reticle pod, transportation equipment and handling steps for the reticle transport pod also need re-planning and adjustment. For example, when a reticle pod is transported by an overhead hoist transport (OHT) system to a process machine (for example, an exposure apparatus), it is necessary for such non-equilateral rectangular reticle pod to be placed in a specific orientation according to existing machine restrictions or process requirements in order to enter the exposure apparatus. For example, before entering the exposure apparatus, the non-equilateral rectangular reticle pod is placed on a load port with the short side of the reticle pod facing the exposure apparatus. However, a load port of a current loading machine lacks an orientation function, and so the reticle pod can only enter the exposure apparatus in a specific orientation when transported to the exposure apparatus. Therefore, additional automated machinery needs to be configured within the exposure apparatus to change the orientation of the non-equilateral rectangular reticle pod to improve sophistication and space usage of the exposure apparatus.

### SUMMARY OF THE INVENTION

In view of the issues above, the present invention provides an orientable semiconductor container adapted to a non-equilateral rectangular reticle pod. An orientating assembly is disposed at a bottom of the reticle pod. The reticle pod is driven to rotate by means of driving the reticle pod by a drive portion to achieve an orientation function, hence solving the issue of orientation inconsistency between an OHT system and long/short sides of a reticle inside a machine.

More specifically, an orientable semiconductor container provided by the present invention is adapted to a non-equilateral rectangular reticle pod, and includes a pod and an orientating assembly disposed at a bottom of the pod. The orientating assembly is configured to cooperate with a drive portion of a load port when the pod is placed on the load port. The orientating assembly rotates the pod from a first direction to a second direction according to a drive stroke provided by the drive portion.

On the basis of the concept above, the orientating assembly includes a rotary seat, and the drive portion is located at or close to a load-in position of the load port, such that the pod comes into contact with the drive portion and rotates in direction along with a movement stroke of load-in of the pod when the pod is located at the load-in position .

On the basis of the concept above, the pod includes an outer pod for accommodating an inner pod, the inner pod is for holding a non-equilateral rectangular reticle, and the outer pod includes a door configured with the orientating assembly. When the outer pod cooperates with the drive portion of the load port to rotate, the inner pod accommodated in the outer pod is able to rotate together relative to the orientating assembly to change direction.

On the basis of the concept above, the pod includes an outer pod for accommodating an inner pod, and the inner pod includes a base configured with the orientating assembly. When the base cooperates with the drive portion of the load port to rotate, a non-equilateral rectangular reticle placed in the inner pod rotates together relative to the orientating assembly to change direction.

On the basis of the concept above, the rotary seat is rotatably connected to the bottom of the pod by a bearing.

On the basis of the concept above, the bottom of the pod is configured with at least one positioning groove to coordinate with and be positioned at at least one set of positioning pins of the load port.

On the basis of the concept above, an angle of rotation from the first direction to the second direction is greater than or equal to 90 degrees.

On the basis of the concept above, the orientating assembly includes a gear disc, the drive portion is a rack, the gear disc and the rack are engaged with each other, and the gear disc rotates the pod from the first direction to the second direction according to a drive stroke provided by the rack.

The present invention further provides an orientation system for a semiconductor container adapted to a non-equilateral rectangular reticle pod. The orientation system for a semiconductor container includes: a load-in track, configured to receive from a load port and transport the non-equilateral rectangular reticle pod; an orientating assembly, disposed at a bottom of the non-equilateral rectangular reticle pod; and a drive portion, disposed on the load port or the load-in track, wherein the orientating assembly cooperates with the drive portion to cause the orientating assembly to rotate the non-equilateral rectangular reticle pod from a first direction to a second direction according to a drive stroke provided by the drive portion.

On the basis of the concept above, an elevator base is further included to transport the non-equilateral rectangular reticle pod on the load port.

On the basis of the concept above, the orientating assembly includes a rotary seat, and the drive portion is located at a load-in position of the load port, such that the non-equilateral rectangular reticle pod comes into contact with the drive portion and rotates in direction along with a movement stroke of load-in of the non-equilateral rectangular reticle pod when the non-equilateral rectangular reticle pod is located at the load-in position.

On the basis of the concept above, the orientating assembly includes a rotary seat, and the drive portion is located on the load-in track that leads to an exposure apparatus, such that the non-equilateral rectangular reticle pod or the rotary seat rotates in direction along with a movement stroke of load-in of the non-equilateral rectangular reticle pod when the non-equilateral rectangular reticle pod or the rotary seat is in contact with the drive portion.

On the basis of the concept above, an angle of rotation from the first direction to the second direction is greater than or equal to 90 degrees.

On the basis of the concept above, the orientating assembly includes a connecting rod and a rotary disc coupled to the connecting rod, and the connecting rod is connected to the bottom of the non-equilateral rectangular reticle pod and configured to come into contact with the drive portion to rotate the non-equilateral rectangular reticle pod.

On the basis of the concept above, the orientating assembly is a gear disc, the drive portion is a rack, the gear disc and the rack are engaged with each other, and the gear disc rotates the non-equilateral rectangular reticle pod from the first direction to the second direction according to a drive stroke of the rack.

### BRIEF DESCRIPTION OF THE DRAWINGS

FIG. 1 is a perspective diagram of a non-equilateral rectangular reticle pod of the present invention;

FIG. 2 is an exploded view of a non-equilateral rectangular reticle pod of the present invention;

FIGS. 3A to 3C are schematic diagrams of a rotation process according to an embodiment of the present invention;

FIG. 4 is a cross-sectional diagram of a base of a non-equilateral rectangular reticle pod according to an embodiment of the present invention;

FIGS. 5A to 5C are schematic diagrams of a rotation process according to another embodiment of the present invention;

FIG. 6 is a cross-sectional diagram of a base of a non-equilateral rectangular reticle pod according to another embodiment of the present invention;

FIGS. 7A to 7D are schematic diagrams of steps of unloading an orientation system for a semiconductor container and moving toward a track in a load port of the present invention; and

FIGS. 8A to 8D are schematic diagrams of steps of changing the orientation in a load-in track of an orientation system for a semiconductor container of the present invention.

### DETAILED DESCRIPTION OF THE EMBODIMENTS

The term “pod” described in the present invention in general refers to a pod for accommodating a reticle, and is not limited to a single pod, a dual pod, an outer pod or an inner pod.

The term “load port” in the present invention in general refers to a device that transfers a pod from a first environment to a second environment of a system, for example, transferring from an atmospheric environment to a low-pressure environment. A “load port” may include a drive device that moves a pod, for example, a vertical elevator or a horizontal mobile conveyor belt. In some configurations, a drive device for a “load port” may extend into a system, and thus the portion of the “load port” extending into the system may be a portion of the “load port”.

The term “drive stroke” described in the present invention refers to a process of a still drive portion coming into contact with a pod in motion, and the drive portion interacts with the pod (for example, dynamically contacting) during this process. The drive portion exhibits a relative still state relative to the pod in motion, and does not necessarily mean that the drive portion is absolutely still.

The term “load-in position” described in the present invention refers to a starting position of a pod about to enter a “load-in track”, and may be a position located in a load port, a position in a system cavity connected to the load port, or a position between the load port and the system cavity. The term “load-in track” in the present invention in general refers to a track for transporting a pod in a system cavity, for example, a horizontal conveyor belt or a vertical elevator leading to an exposure cavity.

The term “elimination zone” described in the present invention refers to a region at a bottom of a pod, and the region does not interfere with operations of other mechanisms (for example, a dynamic coupling slot or a dynamic coupling pin) at the bottom of the pod.

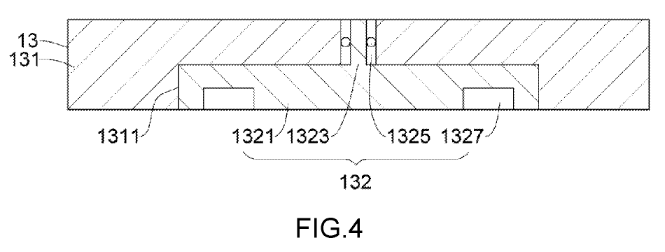

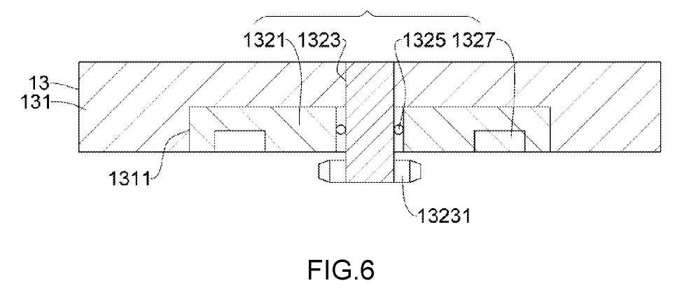

The terms “rotary seat” and “rotary disc” described in the present invention refer to two different implementation elements of an orientating assembly, respectively, as shown in FIGS. 4 and 6. More particularly, the “rotary seat” and the “rotary disc” are individually rotatably connected to a bottom of a pod by different means.

An orientable semiconductor container of the present invention includes a pod, and an orientating assembly 132 (to be described in detail below) disposed at a bottom of the pod. The orientating assembly 132 is configured to cooperate with a drive portion 5 when the pod is placed on the load port. The orientating assembly 132 rotates the pod from a first direction to a second direction according to a drive stroke provided by the drive portion 5.

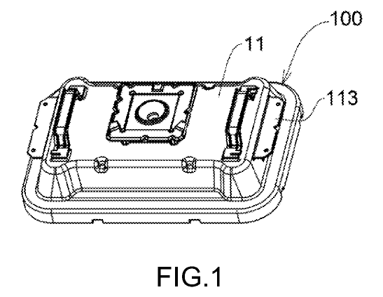

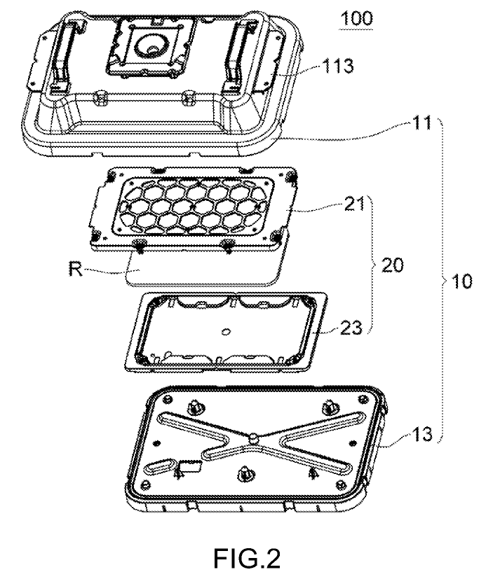

Refer to FIGS. 1 and 2 showing a perspective diagram and an exploded view of a non-equilateral rectangular reticle pod of the present invention, respectively. The present invention provides an orientable semiconductor container adapted to a non-equilateral rectangular reticle pod 100.

The non-equilateral rectangular reticle pod 100 includes an outer pod 10 and an inner pod 20 accommodated in the outer pod 10. The outer pod 10 includes a door 13 and an outer lid 11, and these two may engage with each other to form an accommodation space accommodating the inner pod 20. The outer lid 11 has a handle 113 to facilitate holding or movement. The inner pod 20 includes a base 23 and an upper lid 21, and these two may engage with each other to form an accommodation space accommodating a reticle R. The non-equilateral rectangular reticle pod 100 has a long side and a short side.

In the present invention, the orientating assembly 132 may be disposed at a bottom of the outer pod 10 and/or the inner pod 20, for example, disposed at the door 13 and/or the base 23. In the drawings below, the orientating assembly 132 is disposed in the door 13 as an example; however, the orientating assembly 132 is not limited to only being disposed in the door 13.

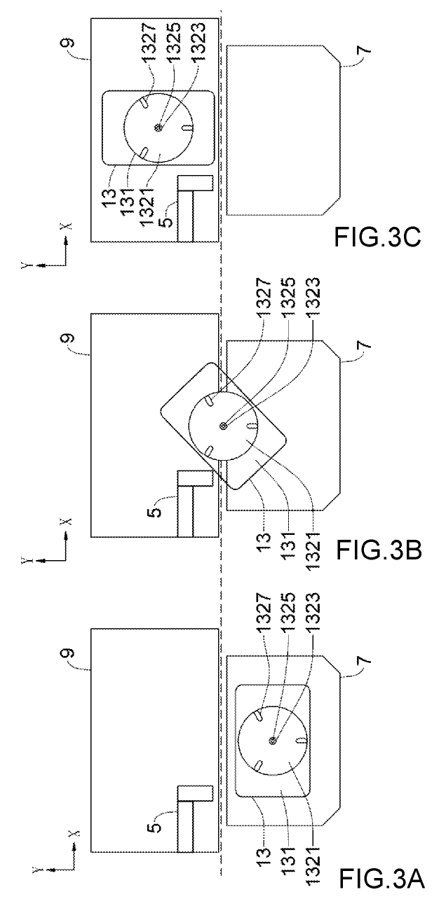

Refer to FIGS. 3A to 3C showing schematic diagrams of a rotation process of an orientable semiconductor container according to an embodiment of the present invention. Along with a movement stroke of load-in of the semiconductor container, the drive portion 5 located at or close to a load-in position of a load port 7 provides the semiconductor container with a drive stroke to rotate the semiconductor container. In this embodiment, during a process of the orientable semiconductor container moving from the load port 7 to a cavity 9, the drive portion 5 comes into contact with the semiconductor container and accordingly rotates the semiconductor container from a first direction to a second direction. In this embodiment, the load port 7 is configured to carry the semiconductor container and has the semiconductor container face the load port 7 and an opening of the cavity 9 by the long side of the semiconductor container. In other embodiments, the load port 7 may also be configured to have the semiconductor container face the load port 7 and the opening of the cavity 9 by the short side of the semiconductor container.

Refer to FIG. 4 showing a cross-sectional diagram of the door 13 according to an embodiment of the present invention. The orientating assembly 132 is disposed at a bottom of the door 13. More specifically, the door 13 includes a seat 131 and the orientating assembly 132, a bottom of the seat 131 is provided with an accommodation chamber 1311, and the orientating assembly 132 is disposed in the accommodation chamber 1311 to prevent interference with machine components.

The orientating assembly 132 is rotatably connected to the seat 131. The orientating assembly 132 includes a rotary seat 1321 and a connecting rod 1323. The connecting rod 1323 is formed on the rotary seat 1321, and is fixedly connected to the rotary seat 1321. The orientating assembly 132 further includes a bearing 1325, and the rotary seat 1321 is rotatably connected to the seat 131 by the bearing 1325. More specifically, the bearing 1325 sleeves the connecting rod 1323 and is disposed between the connecting rod 1323 and the seat 131, allowing the rotary seat 1321 to rotate relative to the seat 131. The connecting rod 1323 and the rotary seat 1321 may be formed integrally, or may be formed by means of fixed connection by multiple components. In another embodiment, the orientating assembly 132 may include a damping assembly to prevent over-rotation between the seat 131 and the rotary seat 1321. In other embodiments, the bearing 1325 may be configured to provide an amount of rotation in a minimum unit, for example, 5 degrees or 15 degrees, to control the resolution of the rotation.

A bottom of the non-equilateral rectangular reticle pod 100 includes at least one set of positioning grooves 1327, which cooperate with and are positioned at at least one set of positioning pins of the load port. In this embodiment, the positioning grooves 1327 are disposed at the bottom of the rotary seat 1321 to better cooperate with the positioning pins and increase the stability of the non-equilateral rectangular reticle pod 100 that is being carried or loaded-in.

Again referring to FIGS. 3A to 3C, with the cooperation of the drive portion 5 and the orientating assembly 132 of the non-equilateral rectangular reticle pod 100, the non-equilateral rectangular reticle pod 100 is rotated from the first direction to the second direction during the process of transportation. Refer to FIG. 3A showing a schematic diagram of the non-equilateral rectangular reticle pod 100 located on the load port 7. The non-equilateral rectangular reticle pod 100 may be placed at a carrying base (not shown), and the positioning groove 1327 is positioned by the positioning pin (not shown) on the load port 7, so as to ensure that the non-equilateral rectangular reticle pod 100 is securely placed or transported. At this point in time, the non-equilateral rectangular reticle pod 100 is in a first direction in which its long side faces the opening of the load port 7.

Then referring to FIG. 3B, during the process of the non-equilateral rectangular reticle pod 100 moving from the load port 7 to the cavity 9, the drive portion 5 located at or close to the load port 7 at this point in time provides a drive stroke to rotate the non-equilateral rectangular reticle pod 100 along with a movement stroke of load-in. More specifically, during the process of the non-equilateral rectangular reticle pod 100 moving from the load port 7 to the cavity 9, since the positioning groove 1327 on the rotary seat 1321 is fixed with the positioning pin on the load port 7, the rotary seat 1321 is made to rotate relative to the seat 131 by means of the drive portion 5 coming into contact with the non-equilateral rectangular reticle pod 100. An angle of rotation is greater than or equal to 90 degrees. In this embodiment, the drive portion 5 is configured to come into contact with the non-equilateral rectangular reticle pod 100 and apply a horizontal force when the non-equilateral rectangular reticle pod 100 moves along a horizontal straight line, wherein the horizontal force and a rotation axis form a torque to impel the non-equilateral rectangular reticle pod 100 to rotate. The drive portion 5 may come into contact with any part of the non-equilateral rectangular reticle pod 100, for example but not limited to, the outer pod 10 or the inner pod 20.

Lastly referring to FIG. 3C, the non-equilateral rectangular reticle pod 100 continues moving to the cavity 9, and along with the movement stroke of load-in of the non-equilateral rectangular reticle pod 100, the drive portion 5 comes into contact with the non-equilateral rectangular reticle pod 100 until the non-equilateral rectangular reticle pod 100 is located in a second direction in which its short side faces the opening of the load port 7; that is, an orientation operation of rotating the non-equilateral rectangular reticle pod 100 from the first direction to the second direction is completed. Thus, the non-equilateral rectangular reticle pod 100 is able to more readily enter other machines subsequently to prevent undesirable effects on process efficiency. More preferably, the drive portion 5 is configured to be able to limit an amplitude of rotation of the non-equilateral rectangular reticle pod 100 during the process of coming into contact with and pressing against the non-equilateral rectangular reticle pod 100, so as to prevent over-rotation of the non-equilateral rectangular reticle pod 100. For example, the drive portion 5 may have a guide surface. In other embodiments, at least one drive portion 5 may be provided; for example, a first drive portion is in charge of rotation of the non-equilateral rectangular reticle pod 100, and a second drive portion is in charge of preventing over-rotation of the non-equilateral rectangular reticle pod 100.

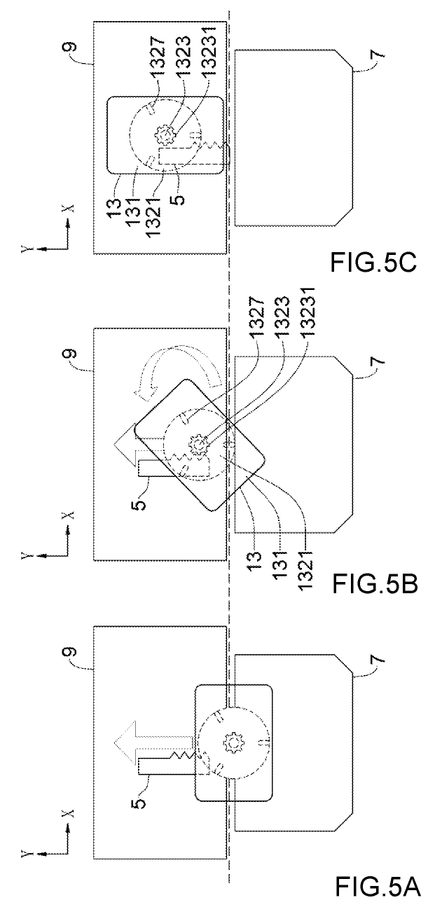

Refer to FIGS. 5A to 5C showing schematic diagrams of a rotation process of an orientable semiconductor container according to another embodiment of the present invention. This embodiment is the same as the foregoing embodiment, along with the movement stroke of load-in of the semiconductor container, the drive portion 5 located at or close to a load-in position of the load port 7 provides the semiconductor container with a drive stroke to change the orientation of the semiconductor container. The difference lies in that, in this embodiment, during the process of the orientable semiconductor container moving from the load port 7 to the cavity 9, the drive portion 5 comes into contact with the orientating assembly of the semiconductor container and accordingly rotates the semiconductor container from the first direction to the second direction.

Refer to FIG. 6 showing a cross-sectional diagram of the door 13 according to an embodiment of the present invention. The orientating assembly 132 is disposed at a bottom of the door 13. More specifically, the door 13 includes a seat 131 and an orientating assembly 132, a bottom of the seat 131 is provided with an accommodation chamber 1311, and the orientating assembly 132 is disposed in the accommodation chamber 1311 to rotatably connect the orientating assembly 132 to the seat 131.

The orientating assembly 132 includes a rotary disc 1321 and a connecting rod 1323 coupled to the rotary disc 1321. The connecting rod 1323 extends downward from a center of the accommodation chamber 1311 of the seat 131 and passes through the rotary disc 1321, allowing the connecting rod 1323 to come into contact with the drive portion 5 to rotate the non-equilateral rectangular reticle pod 100. The orientating assembly 132 further includes a bearing 1325 sleeving the connecting rod 1323 and disposed between the connecting rod 1323 and the rotary disc 1321, allowing the rotary disc 1321 to rotate relative to the seat 131. One end of the connecting rod 1323 away from the seat 131 is provided with a gear disc 13231 to cooperate with the drive portion 5. The connecting rod 1323 and the seat 131 may be formed integrally, or may be formed by means of fixed connection by multiple components.

A bottom of the non-equilateral rectangular reticle pod 100 includes at least one set of positioning grooves 1327, which cooperate with and are positioned at at least one set of positioning pins of the load port 7, and the gear disc 13231 is disposed in an elimination zone of the positioning groove 1327 to prevent interference with other structures. In this embodiment, the positioning grooves 1327 are arranged at the bottom of the rotary disc 1321 to better cooperate with the positioning pins and increase the stability of the non-equilateral rectangular reticle pod 100 that is being carried or loaded-in.

Again referring to FIGS. 5A to 5C, with the cooperation of the drive portion 5 and the orientating assembly 132 of the non-equilateral rectangular reticle pod 100, the non-equilateral rectangular reticle pod 100 is rotated from the first direction to the second direction during the process of transportation. Firstly refer to FIG. 5A showing a schematic diagram of the non-equilateral rectangular reticle pod 100 located on the load port 7. The non-equilateral rectangular reticle pod 100 is placed at a carrying base (not shown), and the positioning groove 1327 is positioned by the positioning pin (not shown) on the carrying base, so as to ensure that the non-equilateral rectangular reticle pod 100 is securely placed or transported. At this point in time, the non-equilateral rectangular reticle pod 100 is in a first direction in which its long side faces the opening of the load port 7.

Then referring to FIG. 5B, during the process of the non-equilateral rectangular reticle pod 100 moving from the load port 7 to the cavity 9, the drive portion 5 located at or close to the load port 7 at this point in time provides a drive stroke to rotate the non-equilateral rectangular reticle pod 100 along with a movement stroke of load-in. More specifically, during the process of the non-equilateral rectangular reticle pod 100 moving from the load port 7 to the cavity 9, since the positioning groove 1327 on the rotary disc 1321 is fixed with the positioning pin on the load port 7, the seat 131 is driven to rotate relative to the rotary disc 1321 by means of the drive portion 5 coming into contact with the non-equilateral rectangular reticle pod 100. In this embodiment, the drive portion 5 is a rack, the gear disc 13231 and the rack are engaged with each other, and the gear disc 13231 rotates the non-equilateral rectangular reticle pod 100 from the first direction to the second direction according to a drive stroke provided by the rack. An angle of rotation is greater than or equal to 90 degrees.

Lastly referring to FIG. 5C, the non-equilateral rectangular reticle pod 100 continues moving to the cavity 9, and the drive portion 5 at this point in time is not in contact with the non-equilateral rectangular reticle pod 100. Along with the movement stroke of load-in of the non-equilateral rectangular reticle pod 100, the non-equilateral rectangular reticle pod 100 is eventually located in the second direction in which its short side faces the opening of the load port 7 to complete changing the orientation of the non-equilateral rectangular reticle pod 100. Thus, the non-equilateral rectangular reticle pod 100 is able to more readily enter other machines subsequently to prevent undesirable effects on process efficiency.

The present invention further provides an orientation system for a semiconductor container adapted to a non-equilateral rectangular reticle pod 100. The orientation system for a semiconductor container includes: a load-in track, configured to receive from a load port 7 and transport the non-equilateral rectangular reticle pod 100; an orientating assembly 132, disposed at a bottom of the non-equilateral rectangular reticle pod 100; and a drive portion 5, disposed on the load port 7 or the load-in track. With the cooperation between the orientating assembly 132 and the drive portion 5, the orientating assembly 132 rotates the non-equilateral rectangular reticle pod 100 from a first direction to a second direction according to a drive stroke provided by the drive portion 5.

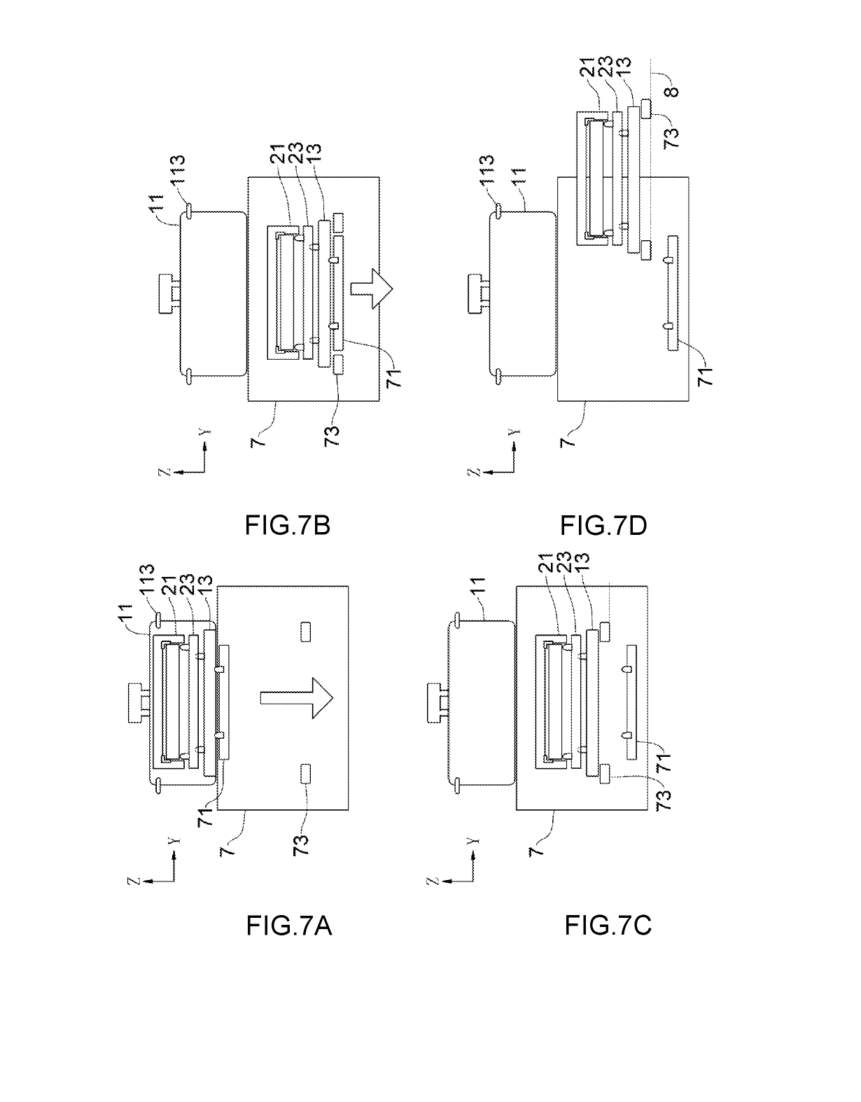

More specifically, refer to FIGS. 7A to 7D showing schematic diagrams of steps of unloading the non-equilateral rectangular reticle pod 100 and moving toward a track in a load port of the present invention. First of all, referring to FIG. 7A, when the non-equilateral rectangular reticle pod 100 is transported onto the load port 7, the non-equilateral rectangular reticle pod 100 is carried at a load port base 71. The outer lid 11 is in a securely held state at this point in time.

Referring to FIGS. 7B and 7C, the load port base 71 lowers such that the outer lid 11 of the reticle pod is removed, the inner pod 20 and the door 13 descend along with the load port base 71 and enter an elevator module, the door 13 becomes pressing against an elevator base 73, and then the load port base 71 is downwardly removed to carry the door 13 on the elevator base 73.

Referring to FIG. 7D, the elevator base 73 carries the inner pod 20 and the door 13, and at this point in time the non-equilateral rectangular reticle pod 100 is in the first direction in which its long side faces the opening of the load port 7. Next, the non-equilateral rectangular reticle pod 100 passes through the track and enters a machine cavity 8.

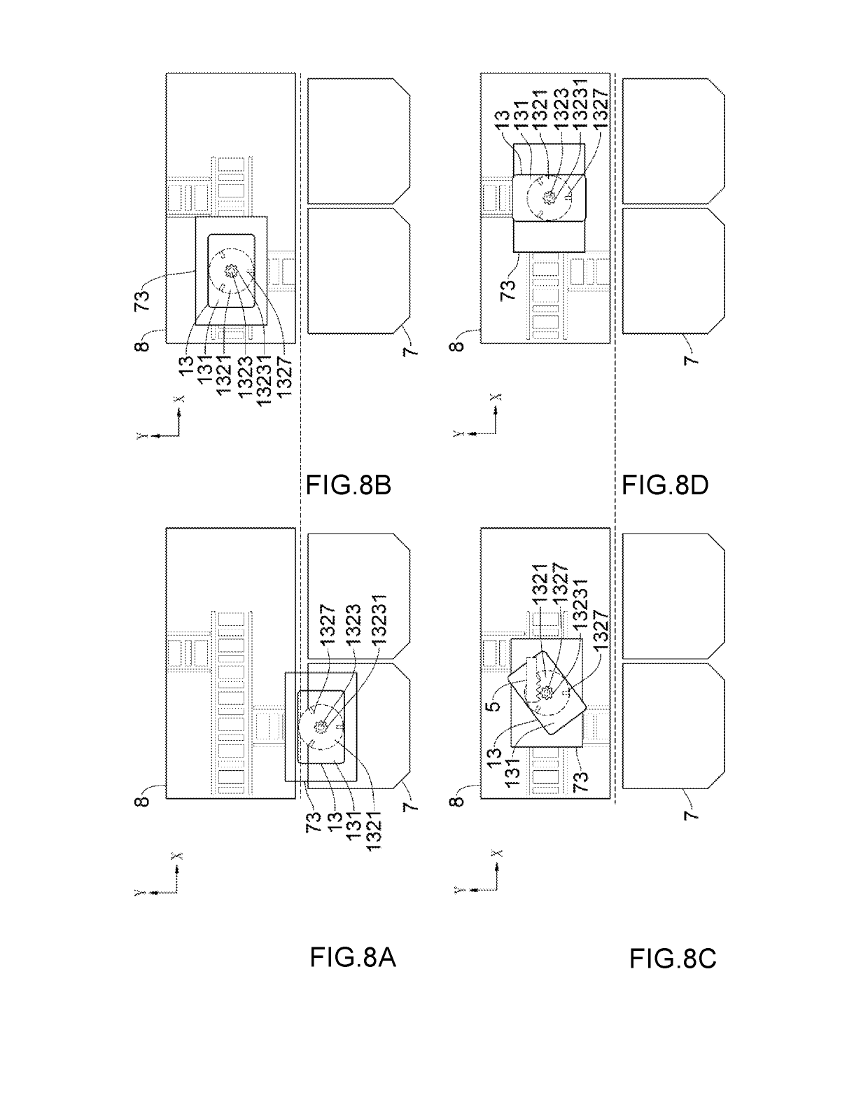

Referring to FIGS. 8A to 8D showing schematic diagrams of steps of changing the orientation of an orientation system for a semiconductor container in a load-in track of the present invention. Firstly referring to FIG. 8A showing a top view of FIG. 7D. When the elevator base 73 carries the inner pod 20 and the door 13 to move along the +Y direction within the load port 7 and arrives at the machine cavity 8, it further moves along the +X direction.

Referring to FIGS. 8B and 8C, during a process of the non-equilateral rectangular reticle pod 100 moving along the +X direction, the drive portion 5 located on the load-in track cooperates with the orientating assembly 132 to change the orientation. The orientating assembly 132 is disposed at the bottom of the door 13. The seat 131 is driven to rotate relative to the rotary disc 1321 by means of the drive portion 5 coming into contact with the orientating assembly 132. In this embodiment, the implementation form in FIG. 6 is taken as an example, that is, the drive portion 5 is a rack, the orientating assembly 132 includes the gear disc 13231, and the gear disc 13231 rotates the non-equilateral rectangular reticle pod 100 from the first direction to the second direction according to a drive stroke provided by the rack.

In this embodiment, the drive portion 5 is disposed on the load-in track as an example; however, the present invention is not limited to such example. The drive portion 5 may be located at or close to a load-in position of the load port 7 to change the orientation during the process of the non-equilateral rectangular reticle pod 100 moving along the +Y direction.

Lastly referring to FIG. 8D, once the orientating assembly 132 separates from the contact with the drive portion 5, along with the movement stroke of load-in of the non-equilateral rectangular reticle pod 100, the non-equilateral rectangular reticle pod 100 is eventually located in the second direction in which its short side faces an opening of an exposure apparatus (not shown) into which it is about to enter, and changing of the orientation is completed.

It should be noted that, although the drawings of the orientation system for a semiconductor container of this embodiment takes the implementation form in FIG. 6 as an example, it does not necessarily mean that the orientation system is merely adapted to the implementation form in FIG. 6 but is also similarly adapted to the implementation form in FIG. 4. Moreover, although the orientating assembly 132 of this embodiment is disposed at the door 13 as an example, the orientating assembly 132 is not limited to being disposed only at the door 13 but may also be disposed on the base 23 of the inner pod 20. For example, in the orientation system for a semiconductor container of this embodiment, the orientating assembly 132 may be disposed on the base 23 of the inner pod 20, and the drive portion 5 comes into contact with the inner pod 20 as shown in FIGS. 3A to 3C, so as to change the orientation of the inner pod 20.

With the orientable semiconductor container and the orientation system for a semiconductor container according to the embodiments of the present invention, a pod is enabled to rotate in direction along with a movement stroke of load-in without additionally transporting the pod to any specific orientation machine. Thus, the issue of transport inability during transportation among different machines can be solved without undesirably affecting process efficiency.

What is claimed is:

1. An orientable semiconductor container adapted to a non-equilateral rectangular reticle pod, the orientable semiconductor container comprising:
a pod; and
an orientating assembly, disposed at a bottom of the pod;
wherein, the orientating assembly is configured to cooperate with a drive portion when the pod is placed on the load port, and the orientating assembly rotates the pod from a first direction to a second direction according to a drive stroke provided by the drive portion.

2. The orientable semiconductor container according to claim 1, wherein the orientating assembly comprises a rotary seat, and the drive portion is located at or close to a load-in position of the load port, such that the pod comes into contact with the drive portion and rotates in direction along with a movement stroke of load-in of the pod when the pod is located at the load-in position.

3. The orientable semiconductor container according to claim 1, wherein the pod comprises an outer pod for accommodating an inner pod, the inner pod is for holding a non-equilateral rectangular reticle, the outer pod comprises a door configured with the orientating assembly, and when the outer pod cooperates with the drive portion of the load port to rotate, the inner pod accommodated in the outer pod is able to rotate together relative to the orientating assembly to change direction.

4. The orientable semiconductor container according to claim 1, wherein the pod comprises an outer pod for accommodating an inner pod, and the inner pod comprises a base configured with the orientating assembly, and when the base cooperates with the drive portion of the load port to rotate, a non-equilateral rectangular reticle placed in the inner pod rotates together relative to the orientating assembly to change direction.

5. The orientable semiconductor container according to claim 2, wherein the rotary seat is rotatably connected to the bottom of the pod by a bearing.

6. The orientable semiconductor container according to claim 1, wherein the bottom of the pod is configured with at least one positioning groove to coordinate with and be positioned at at least one set of positioning pins of the load port.

7. The orientable semiconductor container according to claim 1, wherein an angle of rotation from the first direction to the second direction is greater than or equal to 90 degrees.

8. The orientable semiconductor container according to claim 1, wherein the orientating assembly comprises a gear disc, the drive portion is a rack, the gear disc and the rack are engaged with each other, and the gear disc rotates the pod from the first direction to the second direction according to a drive stroke provided by the rack.

9. An orientation system for a semiconductor container, adapted to a non-equilateral rectangular reticle pod, the orientation system for a semiconductor container comprising:
a load-in track, configured to receive from a load port and transport the non-equilateral rectangular reticle pod;
an orientating assembly, disposed at a bottom of the non-equilateral rectangular reticle pod; and
a drive portion, disposed on the load port or the load-in track;
wherein, the orientating assembly cooperates with the drive portion, such that the orientating assembly rotates the non-equilateral rectangular reticle pod from a first direction to a second direction according to a drive stroke provided by the drive portion.

10. The orientation system for a semiconductor container according to claim 9, further comprising an elevator base configured to transport the non-equilateral rectangular reticle pod on the load port.

11. The orientation system for a semiconductor container according to claim 9, wherein the orientating assembly comprises a rotary seat, and the drive portion is located at a load-in position of the load port, such that the non-equilateral rectangular reticle pod comes into contact with the drive portion and rotates in direction along with a movement stroke of load-in of the non-equilateral rectangular reticle pod when the non-equilateral rectangular reticle pod is located at the load-in position.

12. The orientation system for a semiconductor container according to claim 9, wherein the orientating assembly comprises a rotary seat, and the drive portion is located on the load-in track that leads to an exposure apparatus, such that the non-equilateral rectangular reticle pod or the rotary seat rotates in direction along with a movement stroke of load-in of the non-equilateral rectangular reticle pod when the non-equilateral rectangular reticle pod or the rotary seat comes into contact with the drive portion.

13. The orientation system for a semiconductor container according to claim 9, wherein an angle of rotation from the first direction to the second direction is greater than or equal to 90 degrees.

14. The orientation system for a semiconductor container according to claim 9, wherein the orientating assembly comprises a connecting rod and a rotary disc coupled to the connecting rod, and the connecting rod is connected to the bottom of the non-equilateral rectangular reticle pod and configured to come into contact with the drive portion to rotate the non-equilateral rectangular reticle pod.

15. The orientation system for a semiconductor container according to claim 9, wherein the orientating assembly is a gear disc, the drive portion is a rack, the gear disc and the rack are engaged with each other, and the gear disc rotates the non-equilateral rectangular reticle pod from the first direction to the second direction according to a drive stroke of the rack.
